(19) United States
(12) Patent Application Publication
(10) Pub. No.: US 2011/0175053 A1
(43) Pub. Date: Jul. 21, 2011

(54) NONVOLATILE MEMORY DEVICE AND METHOD FOR MANUFACTURING THE SAME

(75) Inventor: Hiroyuki FUKUMIZU, Kanagawa-ken (JP)

(73) Assignee: KABUSHIKI KAISHA TOSHIBA, Minato-ku (JP)

(21) Appl. No.: 12/886,257

(22) Filed: Sep. 20, 2010

Related U.S. Application Data
(63) Continuation of application No. PCT/JP2008/065590, filed on Aug. 29, 2008.

(30) Foreign Application Priority Data
Mar. 31, 2008 (JP) 2008-094372

(51) Int. Cl. H01L 45/00; H01L 21/8239

(52) U.S. Cl. 257/5; 438/128; 257/E45.003; 257/E21.645

(57) ABSTRACT

According to one embodiment, a nonvolatile memory device includes a substrate, first electrodes, a first and a second interelectrode insulating layer, second electrodes, a memory portion and a first protrusion. The first electrodes are provided on the substrate and extend in a first direction. The first interelectrode insulating layer is provided between the first electrodes. The second electrodes are opposed to the first electrodes and extend in a second direction crossing the first direction. The second interelectrode insulating layer is provided between the second electrodes. The memory portion is provided between the first electrode and the second electrode. The first protrusion is conductive and provided at least one of between the first electrode and the memory portion and between the first interelectrode insulating layer and the memory portion, and between the second electrode and the memory portion and between the second interelectrode insulating layer and the memory portion.

### CROSS-REFERENCE TO RELATED APPLICATIONS

This is a continuation application of International Application PCT/JP2008/065590, filed on Aug. 29, 2008. This application also claims priority to Japanese Application No. 2008-94372, filed on Mar. 31, 2008. The entire contents of each are incorporated herein by reference.

### FIELD

Embodiments described herein relate generally to a nonvolatile memory device and a method for manufacturing the same.

### BACKGROUND

Flash memories widely used as nonvolatile memory devices are regarded as being limited in the improvement of integration density. As a nonvolatile memory device enabling the so-called 4F² cell area, which realizes a higher integration density than flash memories, a cross-point nonvolatile memory device has been drawing attention. The cross-point nonvolatile memory device is configured so that, for instance, a memory portion having variable electrical resistance is sandwiched between two electrodes. JP-A 2006-32728(Kokai) discloses a technique for such a cross-point nonvolatile memory device. In this cross-point nonvolatile memory device, at least one of the opposed electrodes is provided with an electric field concentration portion such as a projection to reduce power consumption and crosstalk.

However, this technique involves a complicated process because an independent projection shaped like e.g. a truncated cone or a half-ellipse is provided only on the electrode. Furthermore, because an independent projection is provided, the position of the projection on the upper and lower electrode is not fixed due to e.g. misalignment in the manufacturing process. Consequently, a large variation occurs in the electric field generated between the upper and lower electrode. This interferes with stable operation.

### BRIEF DESCRIPTION OF THE DRAWINGS

FIGS. 1A and 1B are schematic cross-sectional views illustrating the configuration of a nonvolatile memory device according to a first embodiment;

FIGS. 2A and 2B are schematic views illustrating the configuration of the nonvolatile memory device according to the first embodiment;

FIGS. 3A and 3B are schematic cross-sectional views illustrating the configuration of a nonvolatile memory device of a first comparative example;

FIGS. 4A and 4B are schematic cross-sectional views illustrating the configuration of a nonvolatile memory device of a second comparative example;

FIGS. 5A and 5B are schematic cross-sectional views illustrating the configuration of an alternative nonvolatile memory device according to the first embodiment;

FIGS. 6A and 6B are schematic cross-sectional views illustrating the configuration of a nonvolatile memory device according to a second embodiment;

FIG. 7 is a schematic perspective view illustrating the configuration of the nonvolatile memory device according to the second embodiment;

FIGS. 8A and 8B are schematic cross-sectional views illustrating the configuration of an alternative nonvolatile memory device according to the second embodiment;

FIGS. 9A and 9B are schematic cross-sectional views illustrating the configuration of a nonvolatile memory device according to a third embodiment;

FIG. 10 is a schematic perspective view illustrating the configuration of the nonvolatile memory device according to the third embodiment;

FIGS. 11A and 11B are schematic cross-sectional views illustrating the configuration of a nonvolatile memory device according to a fourth embodiment;

FIGS. 12A and 12B are schematic cross-sectional views illustrating the configuration of a nonvolatile memory device according to a fifth embodiment;

FIGS. 13A and 13B are schematic cross-sectional views illustrating the configuration of an alternative nonvolatile memory device according to the fifth embodiment;

FIGS. 14A and 14B are schematic cross-sectional views illustrating the configuration of a nonvolatile memory device according to a sixth embodiment;

FIG. 15 is a flow chart illustrating a method for manufacturing a nonvolatile memory device according to a seventh embodiment;

FIG. 16 is a flow chart illustrating an alternative method for manufacturing a nonvolatile memory device according to the seventh embodiment;

FIGS. 17A to 17E are schematic cross-sectional views sequentially illustrating the method for manufacturing a nonvolatile memory device according to the seventh embodiment; and

FIGS. 18A and 18B are schematic cross-sectional views subsequent to FIGS. 17A to 17E.

### DETAILED DESCRIPTION

In general, according to one embodiment, a nonvolatile memory device includes a substrate, a plurality of first electrodes, a first interelectrode insulating layer, a plurality of second electrodes, a memory portion and a first protrusion. The plurality of first electrodes is provided on the substrate and extends in a first direction. The first interelectrode insulating layer is provided between the plurality of first electrodes. The plurality of second electrodes is opposed to the plurality of first electrodes and extends in a second direction three-dimensionally crossing the first direction. The second interelectrode insulating layer is provided between the plurality of second electrodes. The memory portion is provided between the first electrode and the second electrode. The first protrusion is conductive and provided at least one of between the first electrode and the memory portion and between the first interelectrode insulating layer and the memory portion, and between the second electrode and the memory portion and between the second interelectrode insulating layer and the memory portion.

In general, according to another embodiment, a nonvolatile memory device includes a substrate, a first electrode, a second electrode, a memory portion, a first protrusion and a second protrusion. The first electrode is provided on the substrate and extends in a first direction. The second electrode is opposed to the first electrode and extends in a second direction three-dimensionally crossing the first direction. The memory portion is provided between the first electrode and the second electrode. The first protrusion is conductive and provided between the first electrode and the memory portion and extends in the first direction. The second protrusion is conductive and provided between the second electrode and the memory portion. The second protrusion extends in the second direction.

In general, according to another embodiment, a method for manufacturing a nonvolatile memory device is disclosed. The method includes: forming a plurality of first electrodes and a first interelectrode insulating layer on a substrate, the plurality of first electrodes extending in a first direction, the first interelectrode insulating layer being provided between the plurality of first electrodes; forming a memory portion on the first electrode and the first interelectrode insulating layer; and forming a plurality of second electrodes and a second interelectrode insulating layer on the memory portion, the plurality of second electrodes extending in a second direction three-dimensionally crossing the first direction, the second interelectrode insulating layer being provided between the plurality of second electrodes. In the method, a conductive protrusion being formed at least one of between the first electrode and the memory portion and between the first interelectrode insulating layer and the memory portion, and between the second electrode and the memory portion and between the second interelectrode insulating layer and the memory portion.

In general, according to another embodiment, a method for manufacturing a nonvolatile memory device is disclosed. The method includes: forming a first electrode extending in a first direction on a substrate; forming a first protrusion on the first electrode, the first protrusion being conductive and extending in the first direction; forming a memory portion on the first electrode and the first protrusion; forming a depression on a surface of the memory portion, the depression extending in a second direction three-dimensionally crossing the first direction on a surface of the memory portion; forming a second protrusion by filling at least part of the depression with a conductive material; and forming a second electrode extending in the second direction on the second protrusion.

Embodiments will now be described in detail with reference to the drawings.

### First Embodiment

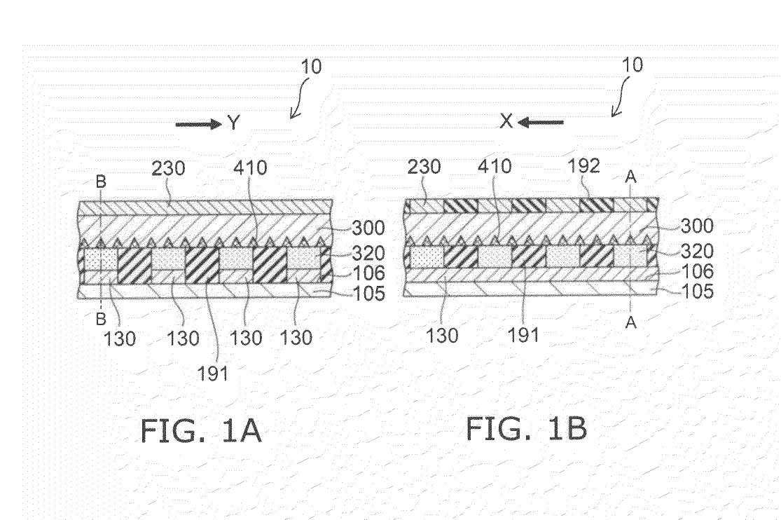

FIGS. 1A and 1B are schematic cross-sectional views illustrating the configuration of a nonvolatile memory device according to a first embodiment.

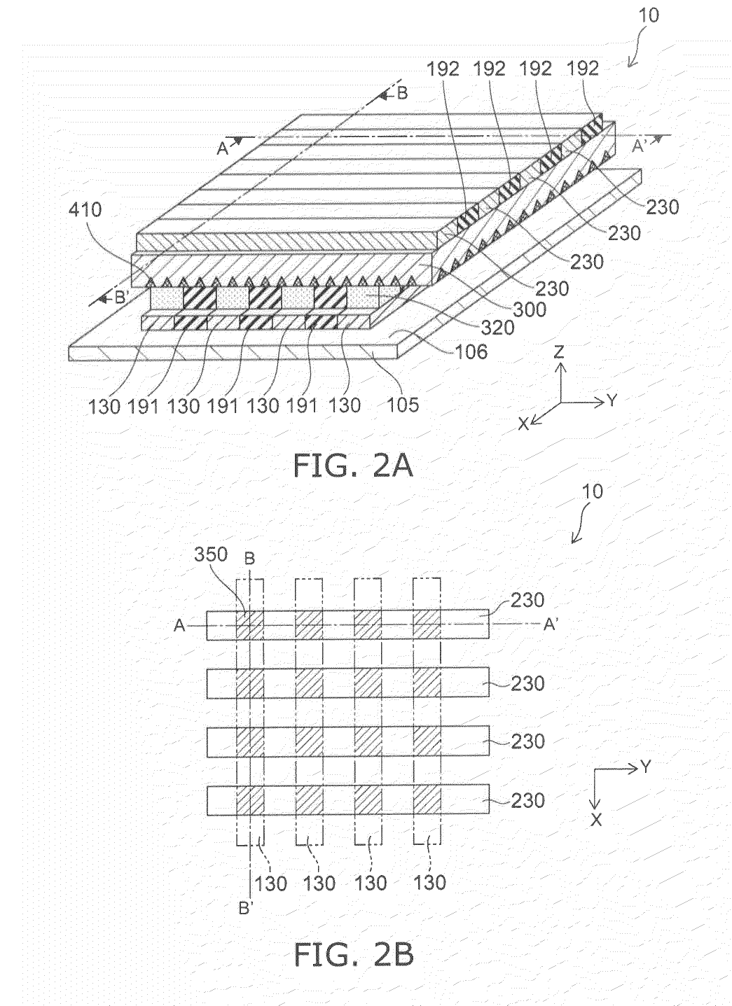

FIGS. 2A and 2B are schematic views illustrating the configuration of the nonvolatile memory device according to the first embodiment.

In this specification and in FIG. 2A and the subsequent figures, components similar to those described previously with reference to earlier figures are labeled with like reference numerals, and the detailed description thereof is omitted as appropriate.

FIGS. 2A and 2B are a schematic perspective view and a schematic transparent plan view, respectively, illustrating the configuration of the nonvolatile memory device according to the first embodiment. FIG. 1A is a cross-sectional view taken along line A-A of FIGS. 2A and 2B, and FIG. 1B is a cross-sectional view taken along line B-B of FIGS. 2A and 2B.

As shown in FIGS. 1A to 2B, the nonvolatile memory device 10 according to the first embodiment includes a plurality of lower electrodes (first electrodes) 130 provided on the major surface 106 of a substrate 105, a plurality of upper electrodes (second electrodes) 230 opposed to the lower electrodes 130, and a memory portion 300 provided between the lower electrode 130 and the upper electrode 230. The lower electrode 130 extends in a first direction, i.e., X-axis direction. The upper electrode 230 extends in a second direction, i.e., Y-axis direction, three-dimensionally crossing (being non-parallel to) the first direction (X-axis direction). The axis orthogonal to the X axis and the Y axis is defined as Z-axis.

A lower interelectrode insulating layer (first interelectrode insulating layer) 191 is provided between the plurality of lower electrodes 130. An upper interelectrode insulating layer (second interelectrode insulating layer) 192 is provided between the plurality of upper electrodes 230.

The nonvolatile memory device 10 further includes a protrusion 410 provided between the lower electrode 130 and the lower interelectrode insulating layer 191 on one hand and the upper electrode 230 on the other. That is, in this example, the protrusion 410 is provided above the lower electrode 130 and the lower interelectrode insulating layer 191.

The substrate 105 can be e.g. a silicon substrate. On this silicon substrate, a driver circuit for driving the nonvolatile memory device can also be provided.

The memory portion 300 can include e.g. various transition metal oxides having electrical resistance changing with the applied voltage, such as nickel oxide (NiO), titanium oxide (TiOₓ), ZnMn₂O₄, ZnFe₂O₄, MnOₓ and PrₓCa₁₋ₓMnO₃. Alternatively, the memory portion 300 can include a phase transition material.

The lower electrode 130 and the upper electrode 230 can include e.g. tungsten, tungsten silicide, aluminum, or copper.

Here, the lower electrode 130 is referred to as bit line (BL), and the upper electrode 230 is referred to as word line (WL). However, alternatively, the lower electrode 130 may be referred to as word line (WL), and the upper electrode 230 may be referred to as bit line (BL).

In the nonvolatile memory device 10, depending on the combination of the potential applied to the lower electrode 130 and the potential applied to the upper electrode 230, the voltage applied to each memory portion 300 is varied. Due to the characteristics of the memory portion 300 in response thereto, information can be stored. Here, to impart directionality to the polarity of the voltage applied to the memory portion 300, for instance, a rectifying element portion 320 having rectifying characteristics can be provided. The rectifying element portion 320 can include e.g. a PIN diode or a MIM (metal-insulator-metal) element.

In the example shown in FIGS. 1A to 2B, the rectifying element portion 320 is provided between the lower electrode 130 and the memory portion 300. However, the rectifying element portion 320 may be provided between the upper electrode 230 and the memory portion 300. Alternatively, the rectifying element portion 320 may be provided in a region other than the region where the lower electrode 130 and the upper electrode 230 are opposed to each other.

Furthermore, in the nonvolatile memory device 10, a barrier metal layer, not shown, can be provided between the lower electrode 130 and the rectifying element portion 320, between the rectifying element portion 320 and the memory portion 300, and between the memory portion 300 and the upper electrode 230. The barrier metal layer can include titanium (Ti) or titanium nitride (TiN).

The lower interelectrode insulating layer 191 and the upper interelectrode insulating layer 192 can include e.g. a silicon oxide film, silicon nitride film, or aluminum nitride film.

The protrusion 410 provided above the lower electrode 130 and the lower interelectrode insulating layer 191 is obtained, for instance, by forming the lower electrode 130 into a prescribed shape, then forming a film constituting the lower interelectrode insulating layer 191 thereon, then performing planarization by chemical mechanical polishing, and then forming a very thin metal film to form fine granular protrusions 410. However, any other method can be used as long as a conductive protrusion 410 can be formed above the lower electrode 130 and the lower interelectrode insulating layer 191.

In the nonvolatile memory device 10 according to this embodiment, the protrusion 410 is provided above the lower electrode 130 and the lower interelectrode insulating layer 191. Thus, the electric field can be concentrated between the lower electrode 130 and the upper electrode 230. That is, the part of the memory portion 300 where the lower electrode 130 and the upper electrode 230 three-dimensionally cross constitutes one memory cell 350. For each of such memory cells 350, the electric field is concentrated by the protrusion 410. Thus, even in the case where the memory portion 300 has a continuous layer structure without being patterned for each memory cell, the occurrence of crosstalk can be suppressed.

Furthermore, the protrusion 410 is provided not only above the lower electrode 130 but also above the lower interelectrode insulating layer 191 flush with the lower electrode 130. That is, the protrusions 410 are not selectively provided only above the lower electrode 130, but randomly provided above the lower electrode 130 and the lower interelectrode insulating layer 191. This facilitates manufacturing. Furthermore, because the protrusions 410 can be randomly provided, the protrusions 410 are not affected by misalignment of the layers during the manufacturing process. Thus, the electric field concentration portion can be stably formed between the lower electrode 130 and the upper electrode 230.

Thus, the nonvolatile memory device 10 according to this embodiment can provide a nonvolatile memory device suppressing the occurrence of crosstalk, being easy to manufacture, and enabling stable operation.

Furthermore, as illustrated in FIGS. 1A and 1B, the protrusion 410 can be made thinner toward the tip. More specifically, the protrusion 410 is provided between the lower electrode 130 and the lower interelectrode insulating layer 191 on one hand and the memory portion 300 on the other. The cross-sectional area of the protrusion 410 in the plane parallel to the major surface of the substrate 105 on the side of the memory portion 300 is smaller than the cross-sectional area in the plane parallel to the major surface of the substrate 105 on the side of the lower electrode 130 and the lower interelectrode insulating layer 191. Thus, the electric field can be concentrated more efficiently.

### First Comparative Example

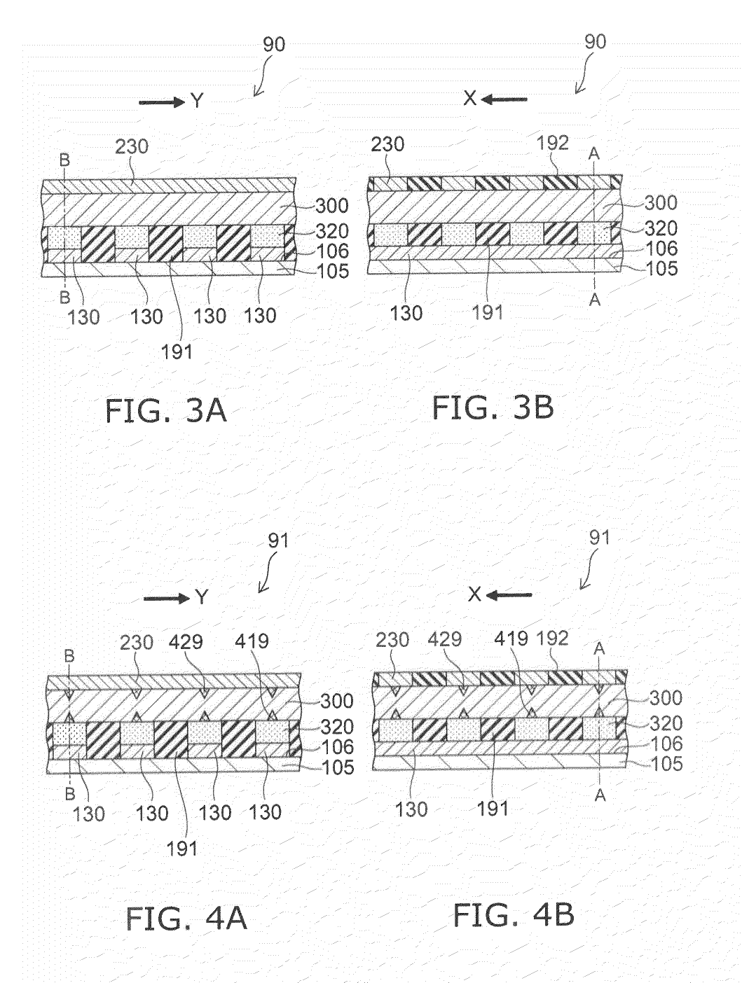

FIGS. 3A and 3B are schematic cross-sectional views illustrating the configuration of a nonvolatile memory device of a first comparative example.

As shown in FIGS. 3A and 3B, in contrast to the nonvolatile memory device 10 according to this embodiment illustrated in FIGS. 1A to 2B, the nonvolatile memory device 90 of the first comparative example has a structure without protrusions 410.

Thus, in the nonvolatile memory device 90 of the first comparative example, each memory cell 350 is affected by the crosstalk of electric field from the adjacent cells, and cannot be properly operated.

### Second Comparative Example

FIGS. 4A and 4B are schematic cross-sectional views illustrating the configuration of a nonvolatile memory device of a second comparative example.

As shown in FIGS. 4A and 4B, in the nonvolatile memory device 91 of the second comparative example, in contrast to the nonvolatile memory device 10 according to this embodiment illustrated in FIGS. 1A to 2B, a protrusion 419 is provided above the lower electrode 130, a protrusion 429 is provided below the upper electrode 230, and no protrusion is provided on the lower interelectrode insulating layer 191 and the upper interelectrode insulating layer 192. In this structure disclosed in Patent Document 1, the protrusion 419 and the protrusion 429 are selectively provided only on the electrode portion. This complicates the process for forming the protrusions 419, 429. Otherwise, the method for forming the protrusions 419, 429 is limited to particular methods. Furthermore, in this case, the relative position of the protrusion 419 and the protrusion 429 is affected by misalignment during the manufacturing process. Thus, a large variation occurs in the state of electric field in each memory cell 350.

In contrast, as described above, in the nonvolatile memory device 10 according to this embodiment, the protrusion 410 is provided not only above the lower electrode 130 but also above the lower interelectrode insulating layer 191 flush with the lower electrode 130. Thus, there is no need to selectively provide the protrusion 410. Furthermore, because the protrusions 410 can be randomly provided, the protrusions 410 are not affected by misalignment of the layers during the manufacturing process. Thus, the electric field concentration portion can be stably formed between the lower electrode 130 and the upper electrode 230.

Thus, the nonvolatile memory device 10 according to this embodiment can provide a nonvolatile memory device suppressing the occurrence of crosstalk, being easy to manufacture, and enabling stable operation.

Here, the aforementioned protrusion 410 is provided above the lower electrode 130 and the lower interelectrode insulating layer 191, but is not limited thereto. As described below, the protrusion 410 can be provided at least one of above the lower electrode 130 and the lower interelectrode insulating layer 191, and below the upper electrode 230 and the upper interelectrode insulating layer 192.

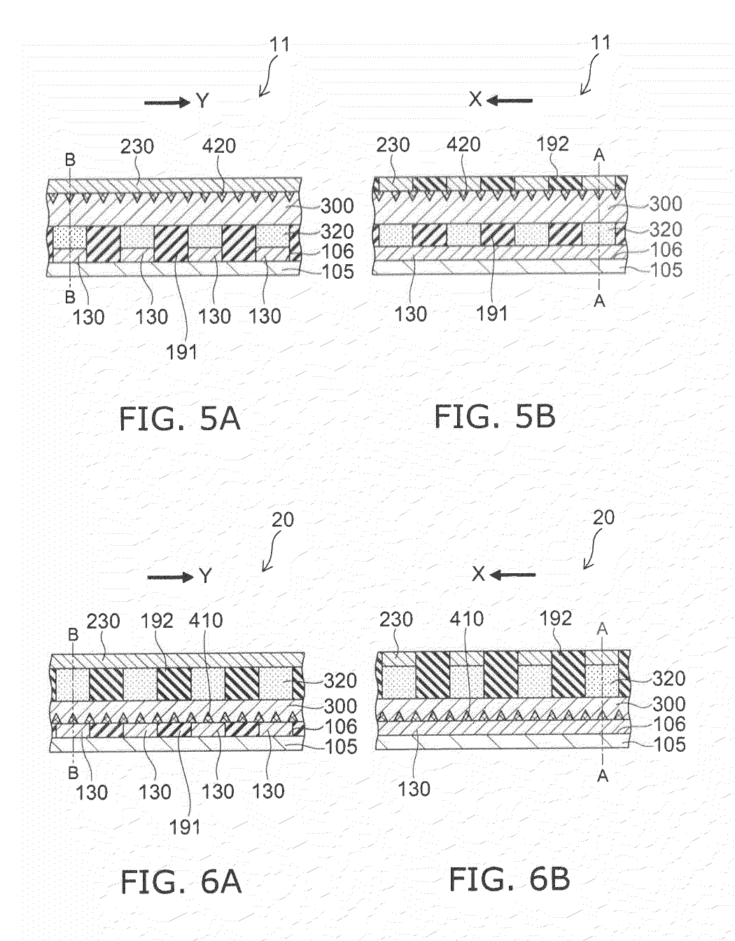

FIGS. 5A and 5B are schematic cross-sectional views illustrating the configuration of an alternative nonvolatile memory device according to the first embodiment.

As shown in FIGS. 5A and 5B, in the alternative nonvolatile memory device 11 according to the first embodiment, a protrusion 420 is provided below the upper electrode 230 and the upper interelectrode insulating layer 192. This protrusion 420 is obtained, for instance, by forming a film constituting the memory portion 300, and then forming a very thin metal film thereon to form fine granular protrusions. However, any other method can be used as long as a conductive protrusion 420 can be formed below the upper electrode 230 and the upper interelectrode insulating layer 192.

The nonvolatile memory device 11 having this structure can also provide a nonvolatile memory device suppressing the occurrence of crosstalk, being easy to manufacture, and enabling stable operation.

Furthermore, as illustrated in FIGS. 5A and 5B, the protrusion 420 can be made thinner toward the tip. More specifically, the protrusion 420 is provided between the upper electrode 230 and the upper interelectrode insulating layer 192 on one hand and the memory portion 300 on the other. The cross-sectional area of the protrusion 420 in the plane parallel to the major surface of the substrate 105 on the side of the memory portion 300 is smaller than the cross-sectional area in the plane parallel to the major surface of the substrate 105 on the side of the upper electrode 230 and the upper interelectrode insulating layer 192. Thus, the electric field can be concentrated more efficiently.

As illustrated in FIGS. 1A and 1B and FIGS. 5A and 5B, in the nonvolatile memory device according to this embodiment, the protrusion 410 can be provided at least one of between the rectifying element portion 320 and the first interelectrode insulating layer 191 on one hand and the memory portion 300 on the other, and between the rectifying element portion 320 and the second interelectrode insulating layer 192 on one hand and the memory portion 300 on the other.

### Second Embodiment

FIGS. 6A and 6B are schematic cross-sectional views illustrating the configuration of a nonvolatile memory device according to a second embodiment.

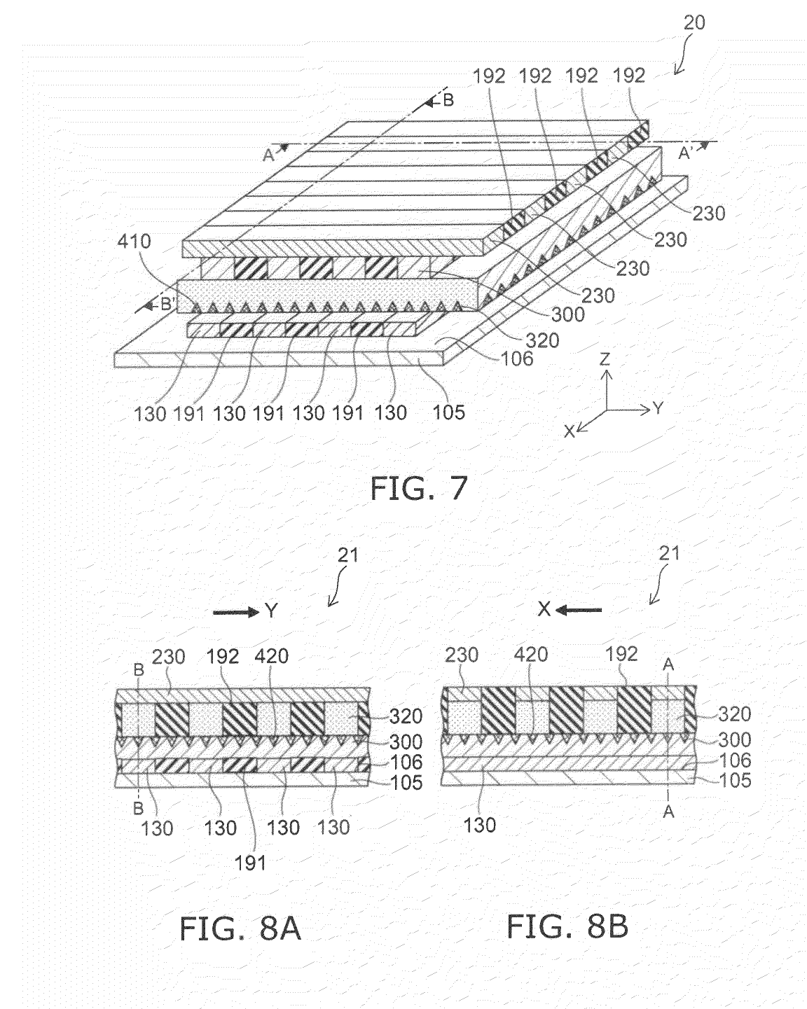

FIG. 7 is a schematic perspective view illustrating the configuration of the nonvolatile memory device according to the second embodiment.

As shown in FIGS. 6A to 7, the nonvolatile memory device 20 according to the second embodiment is different from the nonvolatile memory device 10 illustrated in FIGS. 1A to 2B in that the arrangement of the memory portion 300 and the rectifying element portion 320 is vertically inverted. The remaining configuration is similar to that of the nonvolatile memory device 10 illustrated in FIGS. 1A and 1B. The protrusion 410 is provided above the lower electrode 130 and the lower interelectrode insulating layer 191.

The nonvolatile memory device 20 having this structure can also provide a nonvolatile memory device suppressing the occurrence of crosstalk, being easy to manufacture, and enabling stable operation.

FIGS. 8A and 8B are schematic cross-sectional views illustrating the configuration of an alternative nonvolatile memory device according to the second embodiment.

As shown in FIGS. 8A and 8B, in the alternative nonvolatile memory device 21 according to the second embodiment, a protrusion 420 is provided below the upper electrode 230 and the upper interelectrode insulating layer 192.

The nonvolatile memory device 21 having this structure can also provide a nonvolatile memory device suppressing the occurrence of crosstalk, being easy to manufacture, and enabling stable operation.

### Third Embodiment

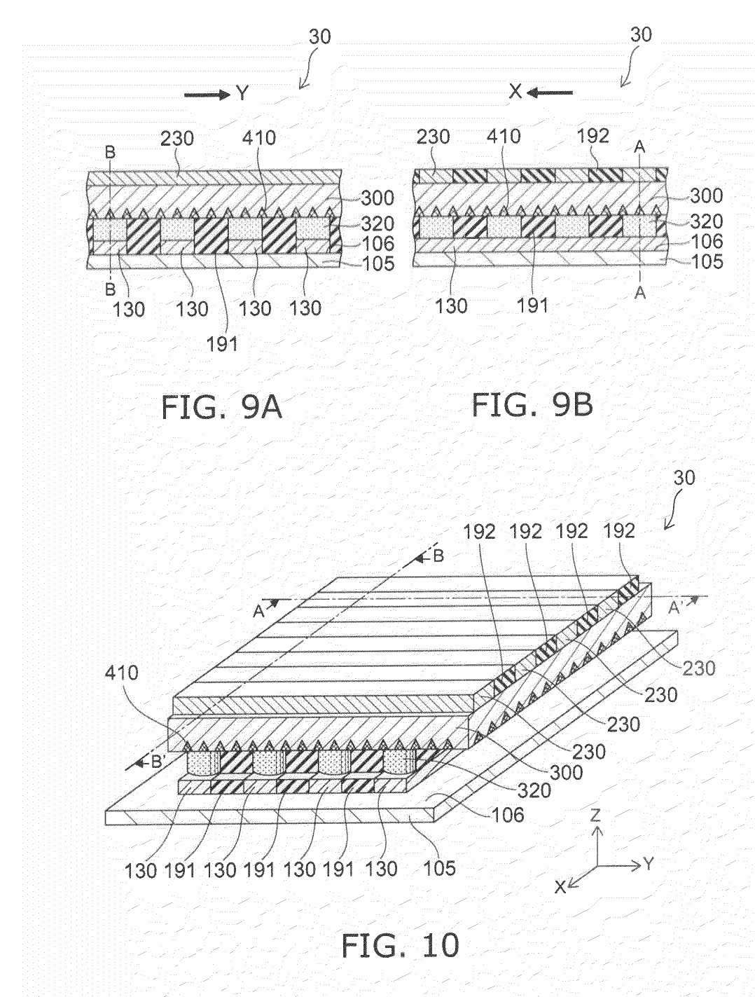

FIGS. 9A and 9B are schematic cross-sectional views illustrating the configuration of a nonvolatile memory device according to a third embodiment.

FIG. 10 is a schematic perspective view illustrating the configuration of the nonvolatile memory device according to the third embodiment.

As shown in FIGS. 9A to 10, in the nonvolatile memory device 30 according to the third embodiment, the rectifying element portion 320 is shaped like a cylinder. The rest can be made similar to the nonvolatile memory device 10 illustrated in FIGS. 1A to 2B, and the description thereof is omitted.

The nonvolatile memory device 30 having this structure can also provide a nonvolatile memory device suppressing the occurrence of crosstalk, being easy to manufacture, and enabling stable operation.

### Fourth Embodiment

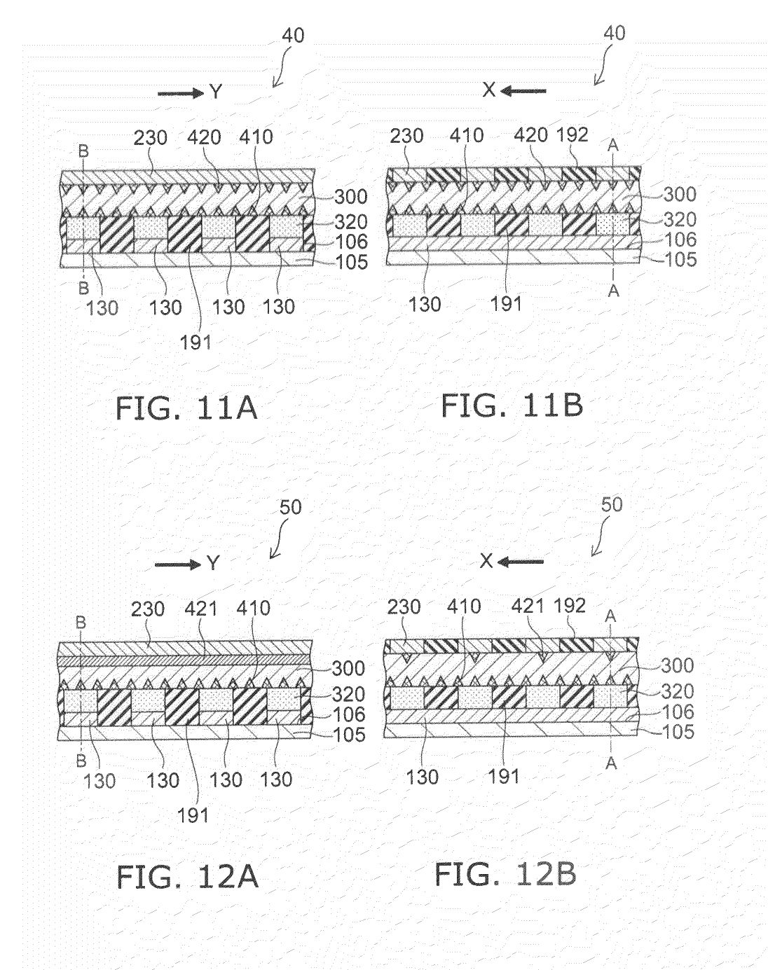

FIGS. 11A and 11B are schematic cross-sectional views illustrating the configuration of a nonvolatile memory device according to a fourth embodiment.

As shown in FIGS. 11A and 11B, in the nonvolatile memory device 40 according to the fourth embodiment, the protrusion 410 and the protrusion 420 are provided above the lower electrode 130 and the lower interelectrode insulating layer 191, and below the upper electrode 230 and the upper interelectrode insulating layer 192, respectively.

The nonvolatile memory device 40 having this structure can also provide a nonvolatile memory device suppressing the occurrence of crosstalk, being easy to manufacture, and enabling stable operation.

### Fifth Embodiment

FIGS. 12A and 12B are schematic cross-sectional views illustrating the configuration of a nonvolatile memory device according to a fifth embodiment.

As shown in FIGS. 12A and 12B, the nonvolatile memory device 50 according to the fifth embodiment includes a plurality of lower electrodes 130 provided on the major surface 106 of a substrate 105, a plurality of upper electrodes 230 opposed to the lower electrodes 130, and a memory portion 300 provided between the lower electrode 130 and the upper electrode 230. A lower interelectrode insulating layer 191 is provided between the plurality of lower electrodes 130. An upper interelectrode insulating layer 192 is provided between the plurality of upper electrodes 230.

In the nonvolatile memory device 50, a protrusion 410 is provided above the lower electrode 130 and the lower interelectrode insulating layer 191. Furthermore, a second protrusion 421 being conductive and extending like a strip in the second direction (Y-axis direction) is provided on the lower surface of the upper electrode 230.

This strip-like second protrusion 421 can be formed, for instance, by forming a film constituting the memory portion 300, then using a suitable mask to etch down the film constituting the memory portion 300 at the position corresponding to the upper electrode 230, and then providing the upper electrode 230.

The nonvolatile memory device 50 having this structure can also provide a nonvolatile memory device suppressing the occurrence of crosstalk, being easy to manufacture, and enabling stable operation.

Furthermore, as illustrated in FIGS. 12A and 12B, the second protrusion 421 can be made thinner toward the tip. More specifically, the cross-sectional area of the second protrusion 421 in the plane parallel to the major surface of the substrate 105 on the side of the memory portion 300 is smaller than the cross-sectional area in the plane parallel to the major surface of the substrate 105 on the side of the second electrode 230. Thus, the electric field can be concentrated more efficiently.

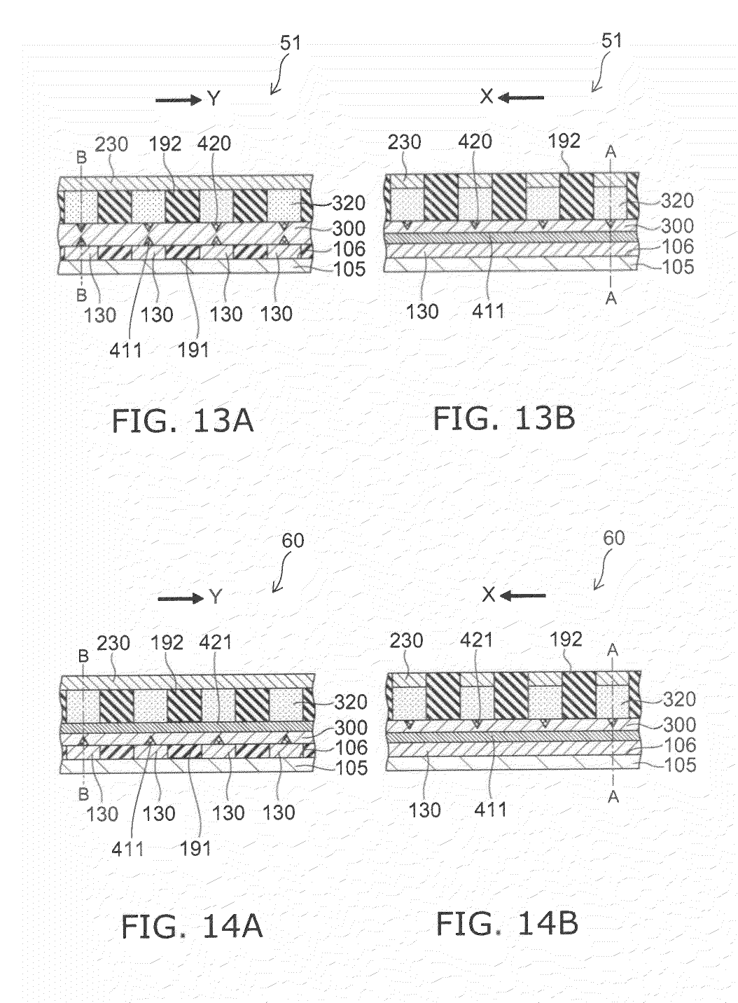

FIGS. 13A and 13B are schematic cross-sectional views illustrating the configuration of an alternative nonvolatile memory device according to the fifth embodiment.

As shown in FIGS. 13A and 13B, in the alternative nonvolatile memory device 51 according to the fifth embodiment, a protrusion 420 is provided below the upper electrode 230 and the upper interelectrode insulating layer 192. Furthermore, a first protrusion 411 (third protrusion) being conductive and extending like a strip in the first direction (X-axis direction) is provided on the upper surface of the lower electrode 130.

This strip-like first protrusion 411 can be obtained, for instance, by forming the lower electrode 130 using a suitable mask so that the lower electrode 130 is shaped like a protrusion in cross-sectional view. Alternatively, the lower electrode 130 can be formed so that conductive particles are segregated. Alternatively, as described later, the first protrusion 411 can be provided by side-etching the film constituting the lower electrode 130.

The nonvolatile memory device 51 having this structure can also provide a nonvolatile memory device suppressing the occurrence of crosstalk, being easy to manufacture, and enabling stable operation.

Furthermore, as illustrated in FIGS. 13A and 13B, the first protrusion 411 can be made thinner toward the tip. More specifically, the cross-sectional area of the first protrusion 411 in the plane parallel to the major surface of the substrate 105 on the side of the memory portion 300 is smaller than the cross-sectional area in the plane parallel to the major surface of the substrate 105 on the side of the first electrode 130. Thus, the electric field can be concentrated more efficiently.

In the foregoing, the first protrusion 411 and the second protrusion 421 are shaped like a strip, but do not need to be shaped like a completely continuous strip. The first protrusion 411 and the second protrusion 421 may include discontinuities in midstream of the strip-like protrusion as long as they have a shape extending in the first direction and the second direction, respectively.

In the embodiments described above, in the case where the rectifying element portion 320 is located between the lower electrode 130 and the memory portion 300, the protrusion 410 or the first protrusion 411 may be provided on the surface of the rectifying element portion 320 on the memory portion 300 side as illustrated in FIGS. 1A and 1B, or on the surface of the lower electrode 130 on the rectifying element portion 320 side (memory portion 300 side). Furthermore, in the case where the rectifying element portion 320 is located between the upper electrode 230 and the memory portion 300, the protrusion 420 or the second protrusion 421 may be provided on the surface of the upper electrode 230 on the memory portion 300 side as illustrated in FIGS. 5A and 5B, or the protrusion 410 or the first protrusion 411 may be provided on the surface of the rectifying element portion 320 on the memory portion 300 side.

### Sixth Embodiment

FIGS. 14A and 14B are schematic cross-sectional views illustrating the configuration of a nonvolatile memory device according to a sixth embodiment.

As shown in FIGS. 14A and 14B, the nonvolatile memory device 60 according to the sixth embodiment includes a lower electrode 130 provided on the major surface 106 of a substrate 105 and extending in the first direction, and an upper electrode 230 opposed to the lower electrode 130 and extending in the second direction three-dimensionally crossing the first direction.

A first protrusion 411 being conductive and extending in the first direction is provided on the upper surface of the lower electrode 130. A second protrusion 421 being conductive and extending in the second direction is provided on the lower surface of the upper electrode 230.

A memory portion 300 is provided between the lower electrode 130 and the first protrusion 411 on one hand and the upper electrode 230 and the second protrusion 421 on the other.

In the nonvolatile memory device 60 according to this embodiment, the strip-like protrusion 411 is provided on the upper surface of the lower electrode 130, and the strip-like protrusion 421 is provided on the lower surface of the upper electrode 230. Hence, the electric field can be concentrated for each memory cell 350 where the lower electrode 130 and the upper electrode 230 three-dimensionally cross each other. Thus, even if the memory portion 300 has a continuous layer structure without being patterned for each memory cell, the occurrence of crosstalk can be suppressed.

Furthermore, the distance between the strip-like first protrusion 411 and second protrusion 421 is not substantially affected by misalignment of the layers during the wafer manufacturing process. Thus, the electric field concentration portion can be stably formed between the lower electrode 130 and the upper electrode 230.

Thus, the nonvolatile memory device 60 according to this embodiment can provide a nonvolatile memory device suppressing the occurrence of crosstalk, being easy to manufacture, and enabling stable operation.

Here, the first protrusion 411 can be made thinner toward the tip. More specifically, the cross-sectional area of the first protrusion 411 in the plane parallel to the major surface of the substrate 105 on the side of the memory portion 300 is smaller than the cross-sectional area in the plane parallel to the major surface of the substrate 105 on the side of the lower electrode 130. Thus, the electric field can be concentrated more efficiently.

Furthermore, the cross-sectional area of the second protrusion 421 in the plane parallel to the major surface of the substrate 105 on the side of the memory portion 300 is smaller than the cross-sectional area in the plane parallel to the major surface of the substrate 105 on the side of the upper electrode 230. Thus, the electric field can be concentrated more efficiently.

In FIGS. 14A and 14B, the second protrusion 421 is provided between the rectifying element portion 320 and the memory portion 300. However, the configuration may be such that at least one of the first protrusion 411 and the second protrusion 421 is provided between the rectifying element portion 320 and the memory portion 300.

### Seventh Embodiment

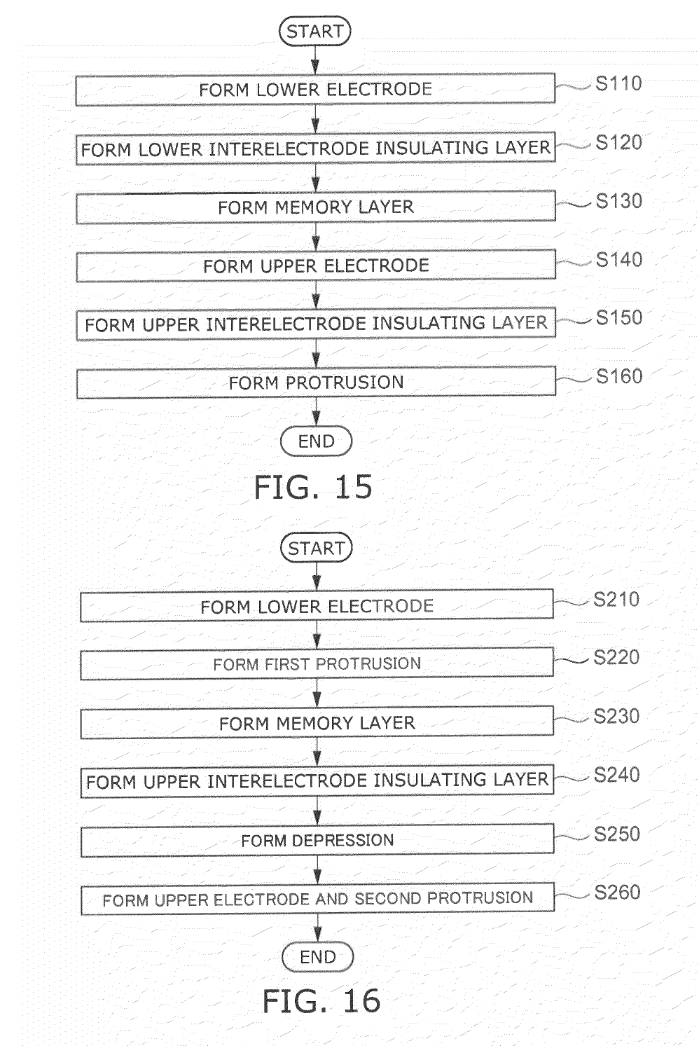

FIG. 15 is a flow chart illustrating a method for manufacturing a nonvolatile memory device according to a seventh embodiment.

As shown in FIG. 15, in the method for manufacturing a nonvolatile memory device according to this embodiment, first, a plurality of lower electrodes 130 extending in the first direction are formed on the major surface 106 of a substrate 105 (step S110).

Next, a lower interelectrode insulating layer 191 is formed between the lower electrodes 130 (step S120).

Next, a memory portion 300 is formed above the lower electrode 130 and the lower interelectrode insulating layer 1.91 (step S130).

Next, above the memory portion 300, a plurality of upper electrodes 230 opposed to the lower electrodes 130 and extending in the second direction three-dimensionally crossing the first direction are formed (step S140).

Next, an upper interelectrode insulating layer 192 is formed between the upper electrodes 230 (step S150).

Next, a conductive protrusion is formed at least one of above the lower electrode 130 and the lower interelectrode insulating layer 191, and below the upper electrode 230 and the upper interelectrode insulating layer 192 (step S160). That is, a protrusion 410 is formed on the upper surface of the lower electrode 130 and the lower interelectrode insulating layer 191, or a protrusion 420 is formed on the lower surface of the upper electrode 230 and the upper interelectrode insulating layer 192. Alternatively, both the protrusion 410 and the protrusion 420 are formed.

However, in the foregoing, steps S110 to S160 can be reordered as long as technically feasible.

For instance, in the case where the protrusion 410 is formed above the lower electrode 130 and the lower interelectrode insulating layer 191 as in the nonvolatile memory device 10 illustrated in FIGS. 1A and 1B, step S160 for forming the protrusion is performed after steps S110 and S120.

In the case where the protrusion 420 is formed below the upper electrode 230 and the upper interelectrode insulating layer 192 as in the nonvolatile memory device 11 illustrated in FIGS. 5A and 5B, for instance, after forming the memory portion 300 (step S130), a depression is formed thereon. Subsequently, the upper electrode 230 is formed (step S140), and the upper interelectrode insulating layer 192 is formed (step S150). Consequently, the protrusion 420 can be formed below the upper electrode 230 and the upper interelectrode insulating layer 192 (step S160).

Thus, the aforementioned nonvolatile memory device according to this embodiment is obtained. That is, the method for manufacturing a nonvolatile memory device according to this embodiment can provide a method for manufacturing a nonvolatile memory device suppressing the occurrence of crosstalk, being easy to manufacture, and enabling stable operation.

FIG. 16 is a flow chart illustrating an alternative method for manufacturing a nonvolatile memory device according to the seventh embodiment.

As shown in FIG. 16, in the alternative method for manufacturing a nonvolatile memory device according to this embodiment, first, a lower electrode 130 extending in the first direction is formed on the major surface 106 of a substrate 105 (step S210).

Next, on the lower electrode 130, a first protrusion 411 being conductive and extending in the first direction is formed (step S220). Here, as described later, the first protrusion 411 is obtained by side-etching the film constituting the lower electrode 130. However, the embodiment is not limited thereto as long as the first protrusion 411 is formed on the lower electrode 130. For instance, the techniques of photolithography and etching may be used.

Next, a memory portion 300 is formed above the lower electrode 130 and the first protrusion 411 (step S230). Here, a rectifying element portion 320 may be formed before or after forming the memory portion 300.

Next, on the upper surface of the memory portion 300, an upper interelectrode insulating layer 192 extending in the second direction three-dimensionally crossing the first direction is formed (step S240).

Next, on the memory portion 300 exposed from the upper interelectrode insulating layer 192, a depression 430 extending in the second direction is formed (step S250).

Next, on the memory portion 300 exposed from the upper interelectrode insulating layer 192, a conductive film is formed. Thus, the upper electrode 230 and the second protrusion 421 below the upper electrode 230 are formed (step S260).

Thus, the nonvolatile memory device with the first protrusion 411 provided above the lower electrode 130 and the second protrusion 421 provided below the upper electrode 230 is obtained. That is, the method for manufacturing a nonvolatile memory device according to this embodiment provides a method for manufacturing a nonvolatile memory device suppressing the occurrence of crosstalk, being easy to manufacture, and enabling stable operation.

In the following, this manufacturing method is described in detail.

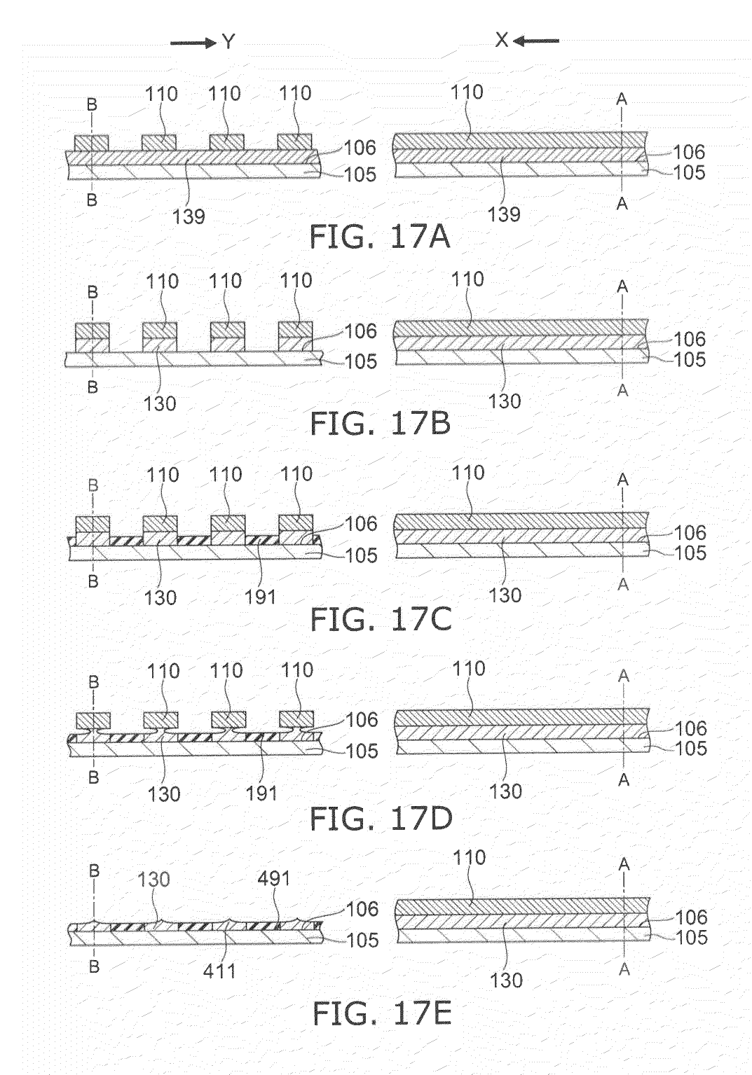

FIGS. 17A to 17E are schematic cross-sectional views sequentially illustrating the method for manufacturing a nonvolatile memory device according to the seventh embodiment.

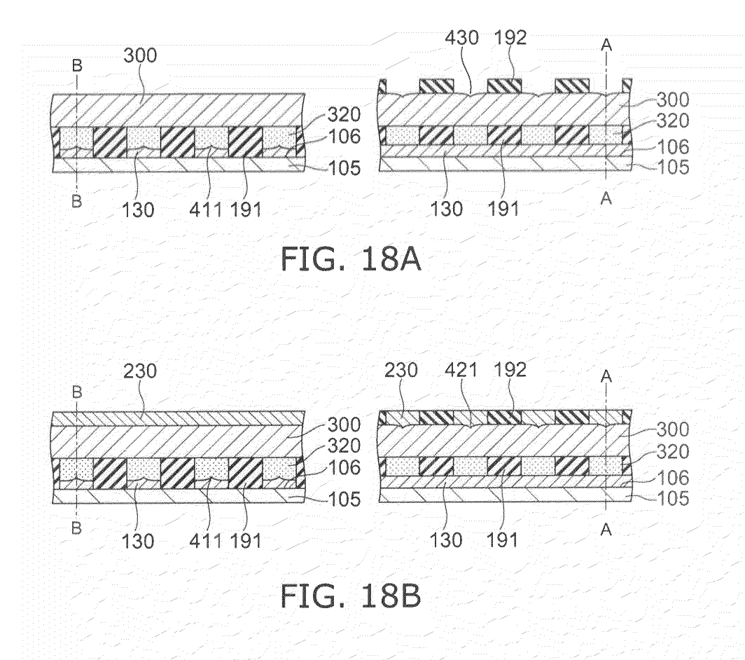

FIGS. 18A and 18B are schematic cross-sectional views subsequent to FIGS. 17A to 17E.

In FIGS. 17A to 18B, the left figure is a cross-sectional view taken along line A-A of FIGS. 2A and 2B, and the right figure is a cross-sectional view taken along line B-B of FIGS. 2A and 2B.

First, as shown in FIG. 17A, on the major surface 106 of a substrate 105, a conductive film 139 constituting the lower electrode is formed. Then, a resist 110 having a prescribed shape is provided.

Next, as shown in FIG. 17B, for instance, the conductive film 139 is etched by the RIE (reactive ion etching) process to form a lower electrode 130.

Next, as shown in FIG. 17C, a silicon oxide film, for instance, is formed in the gap between the lower electrodes 130 to provide a lower interelectrode insulating layer 191. Here, the thickness of the lower interelectrode insulating layer 191 is made thinner than the thickness of the conductive film 139.

Next, as shown in FIG. 17D, while protecting the upper surface of the lower electrode 130 with the resist 110 and protecting the side surface of the lower electrode 130 with the lower interelectrode insulating layer 191, the side surface of the upper portion of the lower electrode 130 is side-etched by e.g. the RIE process or with radicals using a down-flow plasma. That is, under the condition for substantially isotropic etching, etching proceeds so as to narrow the line width of the exposed portion (the side surface of the upper portion) of the lower electrode 130. The etching is continued to reach nearly the center of the line width of the lower electrode 130. Alternatively, from FIG. 17C, without using the resist, insulating film, and plasma, the lower electrode 130 may be selectively etched by wet etching.

Next, as shown in FIG. 17E, by stripping the resist 110, the upper side surface left by side-etching is removed along with the resist 110. Thus, a strip-like, first protrusion 411 being conductive can be formed nearly on the center line of the upper surface of the lower electrode 130.

Thus, the tip of the first protrusion 411 can be thinned. That is, the cross-sectional area of the first protrusion 411 in the plane parallel to the major surface of the substrate 105 can be made larger on the near side of the lower electrode 130 than on the far side.

Next, as shown in FIG. 18A, films constituting the rectifying element portion 320 and the memory portion 300 are respectively formed. An insulating film is formed thereon. Then, by photolithography and etching, an upper interelectrode insulating layer 192 extending in the second direction (Y-axis direction) is formed. Next, the upper interelectrode insulating layer 192 is used as a mask to etch the memory portion 300 by e.g. RIE. Thus, a depression 430 extending in the second direction is formed between the upper interelectrode insulating layers 192.

Next, as shown in FIG. 18B, a conductive film is formed so as to cover the region between the upper interelectrode insulating layer 192, and then planarized by CMP. Thus, an upper electrode 230 is formed. Here, the depression 430 is formed in the memory portion 300 corresponding to the upper electrode 230. Consequently, a first protrusion 421 is formed below the upper electrode 230.

Thus, the nonvolatile memory device with the first protrusion 411 provided above the lower electrode 130 and the second protrusion 421 provided below the upper electrode 230 can be formed.

Thus, the method for manufacturing a nonvolatile memory device according to this embodiment provides a method for manufacturing a nonvolatile memory device suppressing the occurrence of crosstalk, being easy to manufacture, and enabling stable operation.

The embodiments of the invention have been described above with reference to examples. However, the invention is not limited to these examples. For instance, any specific configurations of the components constituting the nonvolatile memory device and the method for manufacturing the same are encompassed within the scope of the invention as long as those skilled in the art can similarly practice the invention and achieve similar effects by suitably selecting such configurations from conventionally known ones.

Furthermore, any two or more components of the examples can be combined with each other as long as technically feasible. Such combinations are also encompassed within the scope of the invention as long as they fall within the spirit of the invention.

Furthermore, those skilled in the art can suitably modify and implement the nonvolatile memory device and the method for manufacturing the same described above in the embodiments of the invention. All the nonvolatile memory devices and the methods for manufacturing the same thus modified are also encompassed within the scope of the invention as long as they fall within the spirit of the invention.

Furthermore, those skilled in the art can conceive various modifications and variations within the spirit of the invention. It is understood that such modifications and variations are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

1-20. (canceled)

21. A nonvolatile memory device comprising:
a substrate;
a plurality of first electrodes provided on the substrate and extending in a first direction;
a first interelectrode insulating layer provided between the plurality of first electrodes;
a plurality of second electrodes opposed to the plurality of first electrodes and extending in a second direction three-dimensionally crossing the first direction;
a second interelectrode insulating layer provided between the plurality of second electrodes;
a memory portion provided between the first electrode and the second electrode; and
a first protrusion, the first protrusion being conductive and provided at least one of between the first electrode and the memory portion and between the first interelectrode insulating layer and the memory portion, and
between the second electrode and the memory portion and between the second interelectrode insulating layer and the memory portion.

22. The device according to claim 21, further comprising:
a second protrusion, the second protrusion being conductive and provided between the second electrode and the memory portion, the second protrusion extending in the second direction,
the first protrusion being provided between the first electrode and the memory portion and between the first interelectrode insulating layer and the memory portion.

23. The device according to claim 22, wherein a cross-sectional area of the second protrusion in a plane parallel to a major surface of the substrate on the memory portion side is smaller than a cross-sectional area of the second protrusion in a plane parallel to the major surface of the substrate on the second electrode side.

24. The device according to claim 21, further comprising:
a third protrusion, the third protrusion being conductive and provided between the first electrode and the memory portion, the third protrusion extending in the first direction,
the first protrusion being provided between the second electrode and the memory portion and between the second interelectrode insulating layer and the memory portion.

25. The device according to claim 24, wherein a cross-sectional area of the third protrusion in a plane parallel to a major surface of the substrate on the memory portion side is smaller than a cross-sectional area of the third protrusion in a plane parallel to the major surface of the substrate on the first electrode side.

26. The device according to claim 21, wherein the memory portion further extends at least one of between the first interelectrode insulating layer and the second electrode and between the second interelectrode insulating layer and the first electrode.

27. The device according to claim 21, wherein the first protrusion is randomly arranged at least one of
between the first electrode and the memory portion and between the first interelectrode insulating layer and the memory portion, and
between the second electrode and the memory portion and between the second interelectrode insulating layer and the memory portion.

28. The device according to claim 21, wherein the first protrusion is provided between the first electrode and the memory portion and between the first interelectrode insulating layer and the memory portion, and a cross-sectional area of the first protrusion in a plane parallel to a major surface of the substrate on the memory portion side is smaller than a cross-sectional area of the first protrusion in a plane parallel to the major surface of the substrate on a side of the first electrode and the first interelectrode insulating layer.

29. The device according to claim 21, wherein the first protrusion is provided between the second electrode and the memory portion and between the second interelectrode insulating layer and the memory portion, and a cross-sectional area of the first protrusion in a plane parallel to a major surface of the substrate on the memory portion side is smaller than a cross-sectional area of the first protrusion in a plane parallel to the major surface of the substrate on a side of the second electrode and the second interelectrode insulating layer.

30. The device according to claim 21, further comprising:
a rectifying element portion provided at least one of between the memory portion and the first electrode and between the memory portion and the second electrode.

31. The device according to claim 30, wherein the first protrusion is provided at least one of
between the rectifying element portion and the memory portion and between the first interelectrode insulating layer and the memory portion, and
between the rectifying element portion and the memory portion and between the second interelectrode insulating layer and the memory portion.

32. A nonvolatile memory device comprising:
a substrate;
a first electrode provided on the substrate and extending in a first direction;
a second electrode opposed to the first electrode and extending in a second direction three-dimensionally crossing the first direction;
a memory portion provided between the first electrode and the second electrode;
a first protrusion, the first protrusion being conductive and provided between the first electrode and the memory portion, the first protrusion extending in the first direction; and
a second protrusion, the second protrusion being conductive and provided between the second electrode and the memory portion, the second protrusion extending in the second direction.

33. The device according to claim 32, wherein a cross-sectional area of the first protrusion in a plane parallel to a major surface of the substrate on the memory portion side is smaller than a cross-sectional area of the first protrusion in a plane parallel to the major surface of the substrate on the first electrode side.

34. The device according to claim 32, wherein a cross-sectional area of the second protrusion in a plane parallel to a major surface of the substrate on the memory portion side is smaller than a cross-sectional area of the second protrusion in a plane parallel to the major surface of the substrate on the second electrode side.

35. The device according to claim 32, further comprising:
a rectifying element portion provided at least one of between the memory portion and the first electrode and between the memory portion and the second electrode.

36. The device according to claim 35, wherein at least one of the first protrusion and the second protrusion is provided between the rectifying element portion and the memory portion.

37. A method for manufacturing a nonvolatile memory device, comprising:
forming a plurality of first electrodes and a first interelectrode insulating layer on a substrate, the plurality of first electrodes extending in a first direction, the first interelectrode insulating layer being provided between the plurality of first electrodes;
forming a memory portion on the first electrode and the first interelectrode insulating layer; and
forming a plurality of second electrodes and a second interelectrode insulating layer on the memory portion, the plurality of second electrodes extending in a second direction three-dimensionally crossing the first direction, the second interelectrode insulating layer being provided between the plurality of second electrodes,
a conductive protrusion being formed at least one of
between the first electrode and the memory portion and between the first interelectrode insulating layer and the memory portion, and
between the second electrode and the memory portion and between the second interelectrode insulating layer and the memory portion.

38. A method for manufacturing a nonvolatile memory device, comprising:
forming a first electrode extending in a first direction on a substrate;
forming a first protrusion on the first electrode, the first protrusion being conductive and extending in the first direction;
forming a memory portion on the first electrode and the first protrusion;
forming a depression on a surface of the memory portion, the depression extending in a second direction three-dimensionally crossing the first;
forming a second protrusion by filling at least part of the depression with a conductive material; and
forming a second electrode extending in the second direction on the second protrusion.

39. The method according to claim 38, wherein the first protrusion is formed by side-etching a film made of a conductive material.

40. The method according to claim 38, wherein a cross-sectional area of the first protrusion in a plane parallel to a major surface of the substrate on a near side of the first protrusion to the first electrode is larger than a cross-sectional area of the first protrusion in a plane parallel to the major surface of the substrate on a far side of the first protrusion to the first electrode, the far side being farther to the first electrode than the near side to the first electrode.
